(19) United States
(12) Patent Application Publication
(10) Pub. No.: US 2026/0333930 A1
(43) Pub. Date: Oct. 22, 2026

(54) Battery Preparation Method, Battery, and Electronic Product

(71) Applicant: Tongwei Solar (Chengdu) Co., Ltd., Chengdu, Sichuan (CN)

(72) Inventors: Hui ZHAO, Chengdu (CN); Shihu LAN, Chengdu (CN); Fanying MENG, Chengdu (CN); Zhengxin LIU, Chengdu (CN)

(21) Appl. No.: 19/113,264

(22) PCT Filed: Apr. 27, 2023
(86) PCT No.: PCT/CN2023/091110

§ 371 Date: Mar. 19, 2025

(30) Foreign Application Priority Data
Sep. 20, 2022 (CN) 202211144583.6

(51) Int. Cl. H10F 71/00; H10F 10/16; H10F 71/10

(52) U.S. Cl. CPC H10F 71/129; H10F 10/16; H10F 71/103; H10F 71/138

(57) ABSTRACT

In one aspect, a battery preparation method includes: sequentially forming a first passivation layer, a first doped layer, a first transparent conducting layer, and a first electrode on the surface of one surface of a substrate; sequentially forming a second passivation layer, a second doped layer, a second transparent conducting layer, and a second electrode on the surface of the other surface of the substrate; and performing ozone surface treatment on the first doped layer and the second doped layer.

This application claims priority to Chinese patent application No. 202211144583.6, filed on Sep. 20, 2022, entitled “BATTERY PREPARATION METHOD, BATTERY, AND ELECTRONIC PRODUCT”, the content of which is hereby incorporated by reference in its entirety.

### TECHNICAL FIELD

The present application relates to the field of batteries, and in particular to a method for preparing a battery, a battery, and an electronic product.

### BACKGROUND

In pursuit of higher photoelectric conversion efficiency, solar cells are updated and iterated very rapidly. Silicon heterojunction solar cells called heterojunction solar cells for short have the advantages of structural symmetry, low-temperature preparation process, high open circuit voltage, good temperature characteristics, and thin silicon wafers, and thus become one category of the new generation crystalline silicon solar cell products.

Conventional methods improve the efficiency of heterojunction solar cells by improving the conversion efficiency of the cells or by increasing the generated power of components. Among them, increasing the short-circuit current of the cells is a method to improve the conversion efficiency of the cells. However, in the conventional methods, while the short-circuit current of the cells is increased, other electrical performance parameters of the cells such as the failure rate of the cells, etc. are often be affected.

### SUMMARY

Accordingly, it is necessary to provide a method for preparing a battery, a battery, and an electronic product, in which the method can increase the short-circuit current of the battery and further improve the battery efficiency while not reducing other electrical performance parameters of the battery.

The present application provides a method for preparing a battery. The method includes the following steps:
S10: providing a substrate, the substrate having a first surface and a second surface opposite to the first surface;
S20: preparing a first passivation layer on the first surface, and preparing a second passivation layer on the second surface;
S30: preparing a first doped layer on the first passivation layer, and preparing a second doped layer on the second passivation layer;
S40: performing an ozone surface treatment on at least one of the first doped layer and the second doped layer;
S50: preparing a first transparent conducting layer on the first doped layer, and preparing a second transparent conducting layer on the second doped layer; and
S60: preparing a first electrode on the first transparent conducting layer, and preparing a second electrode on the second transparent conducting layer.

In an embodiment, performing the ozone surface treatment in step S40 includes: placing at least one of the first doped layer and the second doped layer in an environment with an ozone concentration ranging from 5 ppb to 15 ppb for 1 min to 5 min.

In an embodiment, in step S40 of performing the ozone surface treatment, the ozone is generated by at least one of high voltage discharge, ultraviolet irradiation, and electrolysis.

In an embodiment, in step S20, the first passivation layer and the second passivation layer are each independently prepared by a method selected from the group consisting of plasma enhanced chemical vapor deposition, hot wire chemical vapor deposition, and low-pressure chemical vapor deposition.

In an embodiment, in step S30, the first doped layer and the second doped layer are each independently prepared by a method selected from the group consisting of plasma enhanced chemical vapor deposition, hot wire chemical vapor deposition, and low-pressure chemical vapor deposition.

In an embodiment, in step S50, the first transparent conducting layer and the second transparent conducting layer are prepared in a gas environment with an oxygen content ranging from 5% to 8%.

The present application further provides a battery. The battery is prepared by the method for preparing the battery as described above.

In an embodiment, a distance between an edge of at least one of the first transparent conducting layer and the second transparent conducting layer and an edge of the second doped layer is in a range of 0.2 mm to 0.5 mm.

In an embodiment, conductivity types of the substrate, the first doped layer, and the second doped layer are each independently selected from N-type or P-type.

In an embodiment, the first doped layer and the second doped layer have different conductivity types.

The present application furthermore provides an electronic product. A power supply device of the electronic product includes the battery as described above.

During the above-mentioned battery preparation process, at least one of the first doped layer and the second doped layer is subjected to the ozone surface treatment. The treated surface of the doped layer can effectively combine with the transparent conducting layer, which can inhibit the current leakage risk of the battery caused by the wrapping around of the doped layer.

Furthermore, after the doped layer is subjected to the ozone surface treatment, the area of the transparent conducting layer is increased cooperatively, so that the short-circuit current performance of the battery is improved, while other performances of the battery are not reduced, thereby obtaining the battery having a high short-circuit current, a high fill factor, a low cell failure rate, and a high cell conversion efficiency.

### BRIEF DESCRIPTION OF THE DRAWINGS

In order to better describe and illustrate embodiments and/or examples of the present application, reference may be made to one or more of the drawings. The additional details or examples used to describe the drawings should not be considered limiting of the scope of any one of the disclosed applications, the presently described embodiments and/or examples, and the best mode presently understood of these applications.

FIG. 1 is a structural schematic view of a battery provided in the present application.

### DESCRIPTION OF REFERENCE SIGNS

10: battery, 110: substrate, 120a: first passivation layer, 120b: second passivation layer, 130a: first doped layer, 130b: second doped layer, 140a: first transparent conducting layer, 140b: second transparent conducting layer, 150a: first electrode, 150b: second electrode.

### DETAILED DESCRIPTION

The present application will now be described in detail with reference to the relevant accompanying drawing in order to make the present application more understandable. The preferred embodiment of the present application is show in the drawing. However, the present application can be implemented in many different forms and is not limited to the embodiments described in the present application. On the contrary, the purpose of providing these embodiments is to make the understanding of the disclosure of the present application more thorough and comprehensive.

Unless otherwise defined, all technical and scientific terms used herein have the same meaning as commonly understood by one of ordinary skill in the art to which the present application belongs. The terms used in the description of the present application are merely used for describing specific embodiments, and are not intended to limit the present application. The term “and/or” as used herein includes any or all combinations of two or more associated items listed.

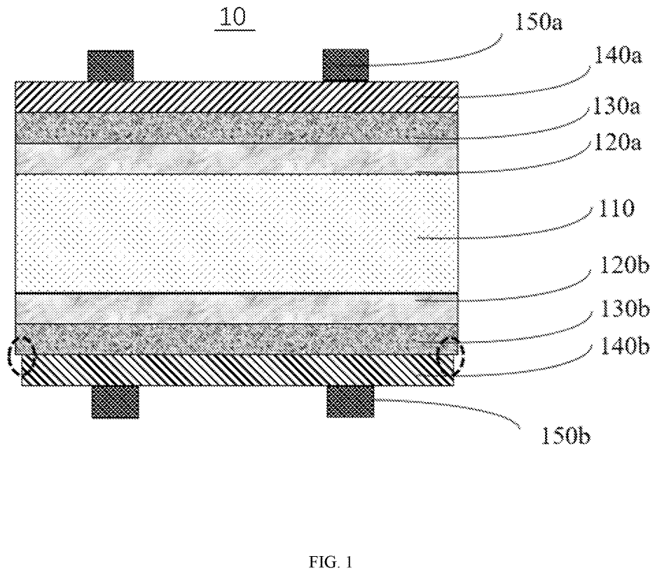

The present application provides a method for preparing a battery 10 as shown in FIG. 1, including the following steps S10 to S60.
Step S10: a substrate 110 is provided, and the substrate 110 has a first surface and a second surface opposite to the first surface.

In a specific example, the substrate 110 is preferably a single crystal silicon substrate 110. Further, prior to providing the substrate 110, the substrate 110 is cleaned and double-sided chemically polished, so as to remove oil stains and cutting damaged layer on the surface of the substrate 110, and form a pyramid light-trapping structure with a clean surface. The thickness of the substrate 110 is 50 μm to 300 μm. Preferably, the thickness of the substrate 110 is 100 μm to 200 μm.
Step S20: a first passivation layer 120a is prepared on the first surface, and a second passivation layer 120b is prepared on the second surface.

In a specific example, in step S20, the first passivation layer 120a and the second passivation layer 120b are each independently prepared by a method selected from plasma enhanced chemical vapor deposition, hot wire chemical vapor deposition, and low-pressure chemical vapor deposition.

Furthermore, in the preparation of the first passivation layer 120a and the second passivation layer 120b, the temperature of the substrate 110 ranges from 150° C. to 250° C., and the pressure in the process chamber ranges from 10 Pa to 400 Pa.

Furthermore, the thickness of the first passivation layer 120a and the second passivation layer 120b ranges from 5 nm to 10 nm. The first passivation layer 120a and the second passivation layer 120b are each independently made of a material selected from at least one of intrinsic amorphous silicon (a-Si: H(i)), intrinsic amorphous silicon oxygen (a-SiOx: H(i)), and intrinsic amorphous silicon carbon (a-SiCx: H(i)).
Step S30: a first doped layer 130a is prepared on the first passivation layer 120a, and a second doped layer 130b is prepared on the second passivation layer 120b.

In a specific example, in step S30, the first doped layer 130a and the second doped layer 130b are each independently prepared by a method selected from plasma enhanced chemical vapor deposition, hot wire chemical vapor deposition, and low-pressure chemical vapor deposition.

Furthermore, the host materials of the first doped layer 130a and the second doped layer 130b are each independently selected from at least one of intrinsic amorphous silicon (a-Si: H(i)), intrinsic amorphous silicon oxygen (a-SiOx: H(i)), and intrinsic amorphous silicon carbon (a-SiCx: H(i)). The thickness of the first doped layer 130a and the second doped layer 130b ranges from 5 nm to 15 nm.

In a specific example, conductivity types of the substrate 110, the first doped layer 130a, and the second doped layer 130b are each independently selected from N-type and P-type. The first doped layer 130a and the second doped layer 130b have different conductivity types. Preferably, one of the first doped layer 130a and the second doped layer 130b has the same conductivity type as that of the substrate 110, and the other of the first doped layer 130a and the second doped layer 130b has a different conductivity type from that of the substrate 110.

It can be understood that when the conductivity type is N-type, the doping element selected from at least one of phosphorus, arsenic, and antimony is doped into the host material of the first doped layer 130a or the host material of the second doped layer 130b. When the conductivity type is P-type, the doping element selected from at least one of boron, gallium, and indium is doped into the host material of the first doped layer 130a or the host material of the second doped layer 130b.
Step S40: an ozone surface treatment is performed on at least one of the first doped layer 130a and the second doped layer 130b.

In a specific example, the ozone surface treatment in step S40 includes: at least one of the first doped layer 130a and the second doped layer 130b is treated in an environment with an ozone concentration ranged from 5 ppb to 15 ppb for 1 min to 5 min.

It can be understood that the doped layer that needs to be treated with ozone can be prepared in advance and then directly subjected to the ozone surface treatment. For example, after being prepared, the doped layer that needs to be treated with ozone is subjected to the ozone surface treatment. Alternatively, after all of the doped layers are prepared, the ozone surface treatment is performed.

Furthermore, in the ozone surface treatment, ozone is generated by at least one of high voltage discharge, ultraviolet irradiation, or electrolysis.

Preferably, the doped layer having the same conductivity type as that of the substrate 110 is subjected to the ozone surface treatment.
Step S50: a first transparent conducting layer 140a is prepared on the first doped layer 130a, and a second transparent conducting layer 140b is prepared on the second doped layer 130b.

Furthermore, the first transparent conducting layer 140a and the second transparent conducting layer 140b are prepared by a method selected from at least one of physical vapor deposition, chemical vapor deposition, and sol-gel method. It can be understood that physical vapor deposition can be but is not limited to vacuum evaporation deposition, sputtering deposition, pulsed laser deposition, or ion plating deposition.

In a specific example, the first transparent conducting layer 140a and the second transparent conducting layer 140b are prepared by physical vapor deposition in a gas environment with an oxygen content of 5% to 8%. In addition to oxygen gas, the gas environment can include argon gas, or a mixture of argon gas and hydrogen gas. If the gas environment includes argon gas and hydrogen gas in addition to oxygen gas, the content of hydrogen gas is less than 2%.

The first transparent conducting layer 140a and the second transparent conducting layer 140b are each independently made of a material selected from at least one of indium oxide doped with tin (ITO), indium oxide doped with tungsten (IWO), indium oxide doped with cesium (ICO), and zinc oxide doped with aluminum (AZO).
Step S60: a first electrode 150a is prepared on the first transparent conducting layer 140a, and a second electrode 150b is prepared on the second transparent conducting layer 140b.

In a specific example, the first electrode 150a and the second electrode 150b are prepared by a method selected from at least one of screen printing, evaporation deposition, magnetron sputtering, inkjet printing, and electroplating.

The first electrode 150a and the second electrode 150b are each independently made of a material selected from silver and copper, which can be but is not limited to a silver paste, silver-coated copper, or copper.

Furthermore, the first electrode 150a and the second electrode 150b include main gate lines and fine gate lines. The height of the main gate lines ranges from 5 μm to 50 μm, and the width of the main gate lines ranges from 60 μm to 150 μm. The height of the fine gate lines ranges from 5 μm to 50 μm, and the width of the fine gate lines ranges from 30 μm to 100 μm.

During the above-mentioned battery preparation process, at least one of the first doped layer 130a and the second doped layer 130b is subjected to the ozone surface treatment. The treated surface of the doped layer can effectively combine with the transparent conducting layer, which can inhibit the current leakage risk of the battery caused by the wrapping around of the doped layer.

The present application further provides a battery 10, which is prepared according to the above-mentioned method for preparing the battery 10.

In a specific example, a distance between an edge of at least one of the first transparent conducting layer 140a and the second transparent conducting layer 140b and an edge of the second doped layer 130b ranges from 0.2 mm to 0.5 mm. It can be understood that the above distance is the dotted box portion shown in FIG. 1.

Furthermore, after the doped layer is subjected to the ozone surface treatment, the area of the transparent conducting layer is increased cooperatively, so that the short-circuit current performance of the battery is improved, while other performances of the battery are not reduced, thereby obtaining the battery having a high short-circuit current, a high fill factor, a low cell failure rate, and a high battery efficiency.

It can be understood that heterojunction solar cells with a leakage current (IRev2) greater than 0.2 A or a parallel resistance (Rsh) less than 50Ω in the IV test are judged as failed cells. On the production line, the above failed cells are defined as scrapped products or unqualified products because such cells, after being made into photovoltaic modules, will have a serious risk of current leakage under the irradiation of sunlight, causing the modules to be broken down, resulting in the scrapping of the entire module, thus causing serious poor battery parameters and appearance defect.

Furthermore, the present application provides an electronic product, in which a power supply device of the electronic product includes the battery as described above.

The following specific examples are provided to further illustrate the preparation method of a battery and the battery of the present application in detail. Unless otherwise specified, the raw materials involved in the following specific examples can all be obtained from commercial sources.

### Example 1

This example provides a battery, and the preparation method thereof includes the following steps.

An N-type single crystal silicon substrate with a thickness of 150 μm is used and cleaned and textured to form a pyramid-shaped light-trapping structure.

Intrinsic amorphous silicon with a thickness of 10 nm is deposited on the front surface of the N-type single crystal silicon substrate as a first passivation layer by the plasma enhanced chemical vapor deposition. Then, N-type doped amorphous silicon with a thickness of 10 nm is deposited on the first passivation layer as a first doped layer.

After the N-type first doped layer is deposited, the surface of the N-type first doped layer is treated with ozone by using a high-voltage discharge ozone generator. The ozone concentration on the surface is 10 ppb, and the ozone treatment time is 5 min.

Intrinsic amorphous silicon with a thickness of 10 nm is deposited as a second passivation layer on the back surface of the N-type single crystal silicon substrate. Then, P-type doped amorphous silicon with a thickness of 12 nm is deposited on the second passivation layer as a second doped layer.

Using a carrier plate with a 0.4 mm mask, an 80 nm thick indium oxide-based second transparent conducting layer doped with 10 wt. % tin is deposited on the P-type second doped layer by the physical vapor deposition technology, in which the content percentage of oxygen gas in the gas atmosphere during the deposition is 6%. Then, an 80 nm thick indium oxide-based first transparent conducting layer doped with 3 wt. % tin is deposited on the N-type first doped layer by the physical vapor deposition technology.

Silver grid lines are printed on the first transparent conducting layer by screen printing as the first electrode, with the height and width of fine grid lines respectively being 20 μm and 55 μm, and the height and width of main grid lines respectively being 22 μm and 110 μm. Silver grid lines are printed on the second transparent conducting layer by screen printing as the second electrode, with the height and width of fine grid lines respectively being 20 μm and 75 μm, and the height and width of main grid lines respectively being 22 μm and 115 μm.

### Example 2

Compared with Example 1, in this example, the N-type first doped layer is not treated with ozone, but the P-type second doped layer is treated with ozone according to the parameters as the same as those in Example 1. The remaining steps are the same as those in Example 1.

### Comparative Example 1

This comparative example provides a battery, and the preparation method thereof includes the following steps.

An N-type single crystal silicon substrate with a thickness of 150 μm is used and cleaned and textured to form a pyramid-shaped light-trapping structure.

Intrinsic amorphous silicon with a thickness of 10 nm is deposited on the front surface of the N-type single crystal silicon substrate as a first passivation layer by the plasma enhanced chemical vapor deposition. Then, N-type doped amorphous silicon with a thickness of 10 nm is deposited on the first passivation layer as a first doped layer.

Intrinsic amorphous silicon with a thickness of 10 nm is deposited as a second passivation layer on the back surface of the N-type single crystal silicon substrate. Then, P-type doped amorphous silicon with a thickness of 12 nm is deposited on the second passivation layer as a second doped layer.

Using a carrier plate with a 0.9 mm mask, an 80 nm thick indium oxide-based second transparent conducting layer doped with 10 wt. % tin is deposited on the P-type second doped layer by the physical vapor deposition technology, in which the content percentage of oxygen gas in the gas atmosphere during the deposition is 6%. Then, an 80 nm thick indium oxide-based first transparent conducting layer doped with 3 wt. % tin is deposited on the N-type first doped layer by the physical vapor deposition technology.

Silver grid lines are printed on the first transparent conducting layer by screen printing as the first electrode, with the height and width of fine grid lines respectively being 20 μm and 55 μm, and the height and width of main grid lines respectively being 22 μm and 110 μm. Silver grid lines are printed on the second transparent conducting layer by screen printing as the second electrode, with the height and width of fine grid lines respectively being 20 μm and 75 μm, and the height and width of main grid lines respectively being 22 μm and 115 μm.

### Comparative Example 2

This comparative example provides a battery, and the preparation method thereof includes the following steps.

An N-type single crystal silicon substrate with a thickness of 150 μm is used and cleaned and textured to form a pyramid-shaped light-trapping structure.

Intrinsic amorphous silicon with a thickness of 10 nm is deposited on the front surface of the N-type single crystal silicon substrate as a first passivation layer by the plasma enhanced chemical vapor deposition. Then, N-type doped amorphous silicon with a thickness of 10 nm is deposited on the first passivation layer as a first doped layer.

Intrinsic amorphous silicon with a thickness of 10 nm is deposited as a second passivation layer on the back surface of the N-type single crystal silicon substrate. Then, P-type doped amorphous silicon with a thickness of 12 nm is deposited on the second passivation layer as a second doped layer.

Using a carrier plate with a 0.9 mm mask, an 80 nm thick indium oxide-based second transparent conducting layer doped with 10 wt. % tin is deposited on the P-type second doped layer by the physical vapor deposition technology, in which the content percentage of oxygen gas in the gas atmosphere during the deposition is 7%. Then, an 80 nm thick indium oxide-based first transparent conducting layer doped with 3 wt. % tin is deposited on the N-type first doped layer by the physical vapor deposition technology.

Silver grid lines are printed on the first transparent conducting layer by screen printing as the first electrode, with the height and width of fine grid lines respectively being 20 μm and 55 μm, and the height and width of main grid lines respectively being 22 μm and 110 μm. Silver grid lines are printed on the second transparent conducting layer by screen printing as the second electrode, with the height and width of fine grid lines respectively being 20 μm and 75 μm, and the height and width of main grid lines respectively being 22 μm and 115 μm.

### Comparative Example 3

This comparative example provides a battery, and the preparation method thereof includes the following steps.

An N-type single crystal silicon substrate with a thickness of 150 μm is used and cleaned and textured to form a pyramid-shaped light-trapping structure.

Intrinsic amorphous silicon with a thickness of 10 nm is deposited on the front surface of the N-type single crystal silicon substrate as a first passivation layer by the plasma enhanced chemical vapor deposition. Then, N-type doped amorphous silicon with a thickness of 10 nm is deposited on the first passivation layer as a first doped layer.

Intrinsic amorphous silicon with a thickness of 10 nm is deposited as a second passivation layer on the back surface of the N-type single crystal silicon substrate. Then, P-type doped amorphous silicon with a thickness of 12 nm is deposited on the second passivation layer as a second doped layer.

Using a carrier plate with a 0.4 mm mask, an 80 nm thick indium oxide-based second transparent conducting layer doped with 10 wt. % tin is deposited on the P-type second doped layer by the physical vapor deposition technology, in which the content percentage of oxygen gas in the gas atmosphere during the deposition is 6%. Then, an 80 nm thick indium oxide-based first transparent conducting layer doped with 3 wt. % tin is deposited on the N-type first doped layer by the physical vapor deposition technology.

Silver grid lines are printed on the first transparent conducting layer by screen printing as the first electrode, with the height and width of fine grid lines respectively being 20 μm and 55 μm, and the height and width of main grid lines respectively being 22 μm and 110 μm. Silver grid lines are printed on the second transparent conducting layer by screen printing as the second electrode, with the height and width of fine grid lines respectively being 20 μm and 75 μm, and the height and width of main grid lines respectively being 22 μm and 115 μm.

### Comparative Example 4

This comparative example provides a battery, and the preparation method thereof includes the following steps.

An N-type single crystal silicon substrate with a thickness of 150 μm is used and cleaned and textured to form a pyramid-shaped light-trapping structure.

Intrinsic amorphous silicon with a thickness of 10 nm is deposited on the front surface of the N-type single crystal silicon substrate as a first passivation layer by the plasma enhanced chemical vapor deposition. Then, N-type doped amorphous silicon with a thickness of 10 nm is deposited on the first passivation layer as a first doped layer.

After the N-type first doped layer is deposited, the surface of the N-type first doped layer is treated with ozone by using a high-voltage discharge ozone generator. The ozone concentration on the surface is 10 ppb, and the ozone treatment time is 5 min.

Intrinsic amorphous silicon with a thickness of 10 nm is deposited as a second passivation layer on the back surface of the N-type single crystal silicon substrate. Then, P-type doped amorphous silicon with a thickness of 12 nm is deposited on the second passivation layer as a second doped layer.

Using a carrier plate with a 0.9 mm mask, an 80 nm thick indium oxide-based second transparent conducting layer doped with 10 wt. % tin is deposited on the P-type second doped layer by the physical vapor deposition technology, in which the content percentage of oxygen gas in the gas atmosphere during the deposition is 6%. Then, an 80 nm thick indium oxide-based first transparent conducting layer doped with 3 wt. % tin is deposited on the N-type first doped layer by the physical vapor deposition technology.

Silver grid lines are printed on the first transparent conducting layer by screen printing as the first electrode, with the height and width of fine grid lines respectively being 20 μm and 55 μm, and the height and width of main grid lines respectively being 22 μm and 110 μm. Silver grid lines are printed on the second transparent conducting layer by screen printing as the second electrode, with the height and width of fine grid lines respectively being 20 μm and 75 μm, and the height and width of main grid lines respectively being 22 μm and 115 μm.

The performances of the batteries prepared in the above examples and comparative examples are shown in the following table:

| | Total | | | | | | | Ave. | Number | |
|---|---|---|---|---|---|---|---|---|---|---|
| | number | Ave. | Ave. | Ave. | Ave. | Ave. | Ave. | IRev | of | Failure |
| | of cells | Eta | Uoc | Isc | FF | Rs | Rsh | 2 | failures | Rate |
| Comparative | 128 | 24.15 | 0.7425 | 9.45 | 84.06 | 0.0019 | 1201 | 0.011 | 2 | 1.0% |
| Example 1 | | | | | | | | | | |
| Comparative | 128 | 24.11 | 0.7429 | 9.47 | 83.72 | 0.0024 | 1820 | 0.004 | 1 | 0.8% |
| Example 2 | | | | | | | | | | |
| Comparative | 128 | 23.96 | 0.7419 | 9.50 | 83.04 | 0.0021 | 110 | 0.043 | 55 | 43% |
| Example 3 | | | | | | | | | | |
| Comparative | 128 | 24.14 | 0.7427 | 9.456 | 83.99 | 0.0021 | 1935 | 0.003 | 0 | 0.0% |
| Example 4 | | | | | | | | | | |
| Example 1 | 128 | 24.22 | 0.7421 | 9.49 | 84.01 | 0.002 | 1342 | 0.007 | 1 | 0.8% |
| Example 2 | 128 | 24.16 | 0.7416 | 9.485 | 83.91 | 0.002 | 2232 | 0.006 | 0 | 0.0% |

Comparative Example 1 is different from Example 1 in that: after the doped layer is prepared, the surface of the doped layer is not treated with ozone by using an ozone generator, and the second transparent conducting layer is prepared by using a carrier plate with a 0.9 mm mask.

Comparative Example 2 is different from Example 1 in that: after the doped layer is prepared, the surface of the doped layer is not treated with ozone by using an ozone generator; the second transparent conducting layer is prepared by using a carrier plate with a 0.9 mm mask; and among the process parameters for preparing the first transparent conducting layer, the content of oxygen gas in the gas atmosphere is adjusted from 6% to 7.1%. Compared to Comparative Example 1, its final short-circuit current (Isc) increases, but the fill factor (FF) decreases, and the final battery efficiency (Eta) has no increase, that is, although the short-circuit current (Isc) can be improved, the fill factor (FF) decreases significantly, and the purpose of improving the battery efficiency cannot be achieved.

Comparative Example 3 is different from Example 1 in that: after the doped layer is prepared, the surface of the doped layer is not treated with ozone by using an ozone generator. Although the short-circuit current (Isc) of the battery is significantly improved, other parameters are greatly reduced, especially the failure rate is greatly increased, which ultimately leads to no increase in battery efficiency (Eta).

Comparative Example 4 is different from Example 1 in that: the second transparent conducting layer is prepared by using a carrier plate with a 0.9 mm mask. Except for smaller leakage current (IRev2) and smaller failure rate, other electrical performances are not much different from those of Comparative Example 1, and the battery efficiency (Eta) has no increase.

In Example 1, after the doped layer is prepared, the surface of the doped layer is treated with ozone by using an ozone generator, and the second transparent conducting layer is prepared by using a carrier plate with a 0.4 mm mask. While ensuring that other electrical performance parameters are not greatly affected, the prepared battery has significantly improved short-circuit current (Isc), ultimately leading to an increase in battery efficiency (Eta).

According to the battery preparation method provided in the present application, after the doped layer is subjected to the ozone surface treatment, the area of the transparent conducting layer is increased cooperatively, so that the short-circuit current performance of the battery is improved, while other performances of the battery are not reduced, thereby obtaining the battery having a high short-circuit current, a high fill factor, a low cell failure rate, and a high battery efficiency.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present application.

The above-described embodiments are only several implementations of the present application, and the descriptions are relatively specific and detailed, but they should not be construed as limiting the scope of the present application. It should be understood by those of ordinary skill in the art that various modifications and improvements can be made without departing from the concept of the present application, and all fall within the protection scope of the present application. Therefore, the patent protection of the present application shall be defined by the appended claims.

1. A method for preparing a battery, comprising the following steps:
S10: providing a substrate, the substrate having a first surface and a second surface opposite to the first surface;
S20: preparing a first passivation layer on the first surface, and preparing a second passivation layer on the second surface;
S30: preparing a first doped layer on the first passivation layer, and preparing a second doped layer on the second passivation layer;
S40: performing an ozone surface treatment on at least one of the first doped layer and the second doped layer;
S50: preparing a first transparent conducting layer on the first doped layer, and preparing a second transparent conducting layer on the second doped layer; and
S60: preparing a first electrode on the first transparent conducting layer, and preparing a second electrode on the second transparent conducting layer.

2. The method for preparing the battery according to claim 1, wherein performing the ozone surface treatment in step S40 comprises: placing at least one of the first doped layer and the second doped layer in an environment with an ozone concentration ranging from 5 ppb to 15 ppb for 1 min to 5 min.

3. The method for preparing the battery according to claim 1, wherein in step S40 of performing the ozone surface treatment, the ozone is generated by at least one of high voltage discharge, ultraviolet irradiation, and electrolysis.

4. The method for preparing the battery according to claim 1, wherein in step S20, the first passivation layer and the second passivation layer are each independently prepared by a method selected from the group consisting of plasma enhanced chemical vapor deposition, hot wire chemical vapor deposition, and low-pressure chemical vapor deposition.

5. The method for preparing the battery according to claim 1, wherein in step S30, the first doped layer and the second doped layer are each independently prepared by a method selected from the group consisting of plasma enhanced chemical vapor deposition, hot wire chemical vapor deposition, and low-pressure chemical vapor deposition.

6. The method for preparing the battery according to claim 1, wherein in step S50, the first transparent conducting layer and the second transparent conducting layer are prepared in a gas environment with an oxygen content ranging from 5% to 8%.

7. A battery prepared by the method for preparing the battery according to claim 1.

8. The battery according to claim 7, wherein a distance between an edge of at least one of the first transparent conducting layer and the second transparent conducting layer and an edge of the second doped layer is in a range of 0.2 mm to 0.5 mm.

9. The battery according to claim 7, wherein conductivity types of the substrate, the first doped layer, and the second doped layer are each independently selected from N-type or P-type.

10. The battery according to claim 7, wherein the first doped layer and the second doped layer have different conductivity types.

11. An electronic product, wherein a power supply device of the electronic product comprises the battery according to claim 7.
